(19) United States
(12) Patent Application Publication
(10) Pub. No.: US 2024/0371631 A1
(43) Pub. Date: Nov. 7, 2024

(54) FILM FORMING METHOD AND FILM FORMING APPARATUS

(71) Applicant: TOKYO ELECTRON LIMITED, Tokyo (JP)

(72) Inventors: Munehito KAGAYA, Nirasaki City, Yamanashi (JP); Yusuke SUZUKI, Nirasaki City, Yamanashi (JP); Yuji OTSUKI, Nirasaki City, Yamanashi (JP)

(21) Appl. No.: 18/556,569

(22) PCT Filed: Apr. 11, 2022
(86) PCT No.: PCT/JP2022/017517

§ 371 Date: Oct. 20, 2023

(30) Foreign Application Priority Data
Apr. 21, 2021 (JP) 2021-071940

(51) Int. Cl. H01L 21/02; C23C 16/34; C23C 16/44; C23C 16/455; C23C 16/52; H01J 37/32

(52) U.S. Cl. CPC H01L 21/02315; C23C 16/345; C23C 16/4408; C23C 16/45542; C23C 16/52; H01J 37/32449; H01L 21/0217; H01L 21/02274; H01L 21/0228; H01J 2237/332

(57) ABSTRACT

A film forming method according to one aspect of the present disclosure includes: forming an adsorption-inhibiting region by supplying an adsorption-inhibiting gas to the substrate; adsorbing a silicon-containing gas onto a region excluding the adsorption-inhibiting region; and forming a silicon nitride film by exposing the substrate, onto which the silicon-containing gas has been adsorbed, to plasma generated from a nitriding gas, wherein the nitriding gas includes a nitrogen-containing gas and an inert gas, and the nitrogen-containing gas has a flow rate greater than a flow rate of the inert gas.

### TECHNICAL FIELD

The present disclosure relates to a film forming method and a film forming apparatus.

### BACKGROUND

In semiconductor manufacturing processes, it is required to embed a film in a recess having a high aspect ratio without voids (gaps) along with miniaturization of structures. As one example of a process of embedding a film in a recess, a technique in which deposition and etching are alternately repeated to embed the film from the bottom of the recess in a bottom-up manner is known (see, e.g., Patent Document 1). Another example of the process of embedding a film in a recess is a technique in which an adsorption-inhibiting gas is adsorbed near an opening of the recess to prevent deposition of a film near the opening, thereby embedding the film from the bottom of the recess in a bottom-up manner (see, e.g., Patent Document 2).

### PRIOR ART DOCUMENTS

### Patent Documents

Patent Document 1: Japanese Laid-Open Publication No. 2014-112668
Patent Document 2: Japanese Laid-Open Publication No. 2018-137369

The present disclosure provides a technique capable of suppressing generation of voids, when performing embedding with respect to a recess using adsorption inhibition, through a shape control during the embedding.

### SUMMARY

A film forming method according to one aspect of the present disclosure forms a film in a recess formed in a surface of a substrate, and includes: forming an adsorption-inhibiting region by supplying an adsorption-inhibiting gas to the substrate; adsorbing a silicon-containing gas onto a region excluding the adsorption-inhibiting region; and forming a silicon nitride film by exposing the substrate, onto which the silicon-containing gas has been adsorbed, to plasma generated from a nitriding gas, wherein the nitriding gas includes a nitrogen-containing gas and an inert gas, and the nitrogen-containing gas has a flow rate greater than a flow rate of the inert gas.

According to the present disclosure, it is possible to suppress generation of voids, when performing embedding with respect to a recess using adsorption inhibition, through a shape control during the embedding

### BRIEF DESCRIPTION OF DRAWINGS

FIG. 1 is a schematic cross-sectional view illustrating an example of a film forming apparatus according to an embodiment.

FIG. 2 is a flowchart illustrating an example of a film forming method according to an embodiment.

FIG. 3 is a flowchart illustrating an example of a process of forming an adsorption-inhibiting region.

FIG. 4 is a diagram illustrating results obtained by evaluating an embedding property of a silicon nitride film with respect to a trench.

FIG. 5 is a diagram illustrating evaluation results of WER of the silicon nitride film embedded in the trench.

### DETAILED DESCRIPTION

Hereinafter, non-limiting exemplary embodiments of the present disclosure will be described with reference to the accompanying drawings. In all the accompanying drawings, the same or corresponding members or components will be denoted by the same or corresponding reference numerals, and redundant descriptions thereof will be omitted.

### [Film Forming Apparatus]

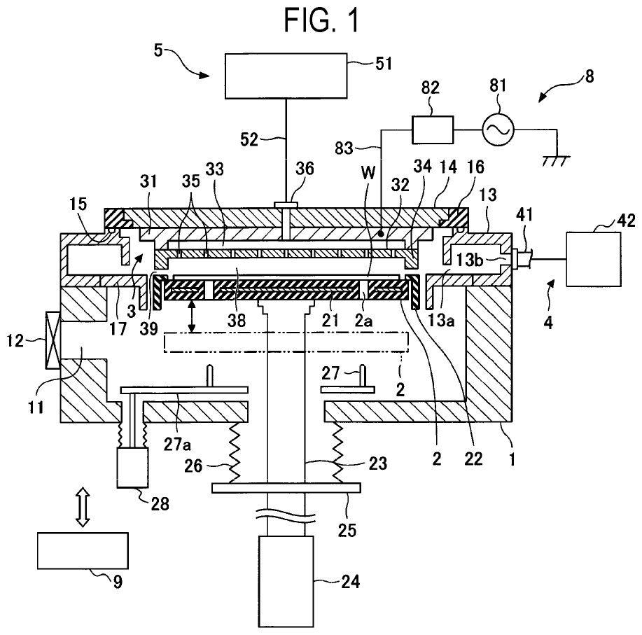

An example of a film forming apparatus according to an embodiment will be described with reference to FIG. 1. The film forming apparatus includes a processing container 1, a stage 2, a shower head 3, an exhauster 4, a gas supplier 5, an RF power supplier 8, a controller 9, and the like.

The processing container 1 is made of a metal such as aluminum, and has a substantially cylindrical shape. The processing container 1 is configured to accommodate a wafer W, which is an example of a substrate. A loading/unloading port 11 for loading or unloading the wafer W therethrough is formed in a sidewall of the processing container 1. A gate valve 12 opens and closes the loading/unloading port 11. An annular exhaust duct 13 having a rectangular cross sectional shape is provided on a main body of the processing container 1. A slit 13a is formed in the exhaust duct 13 along an inner peripheral surface. An exhaust port 13b is formed in an outer wall of the exhaust duct 13. A ceiling wall 14 is provided on a top surface of the exhaust duct 13 to close a top opening of the processing container 1 via an insulator member 16. A space between the exhaust duct 13 and the insulator member 16 is airtightly sealed with a seal ring 15. A partition member 17 vertically partitions an interior of the processing container 1 when the stage 2 (and a cover member 22) has been raised to a processing position to be described later.

The stage 2 horizontally supports the wafer W within the processing container 1. The stage 2 is formed in the shape of a disk having a size corresponding to the wafer W, and is supported by a support member 23. The stage 2 is made of a ceramic material such as AlN, or a metal material such as an aluminum or nickel alloy. A heater 21 is built in the stage 2 to heat the wafer W. The heater 21 generates heat upon receiving power from a heater power supply (not illustrated). Then, the wafer W is controlled to have a predetermined temperature by controlling an output of the heater 21 in response to a temperature signal of a thermocouple (not illustrated) provided near a top surface of the stage 2. The cover member 22, which is made of ceramics such as alumina, is provided on the stage 2 so as to cover an outer peripheral region of the top surface and a side surface of the stage 2.

The support member 23 is provided on a bottom surface of the stage 2 to support the stage 2. The support member 23 passes through a hole formed in a bottom wall of the processing container 1 from the center of the bottom surface of the stage 2, thus extending downward of the processing container 1. A lower end of the support member 23 is connected to a lifting mechanism 24. The lifting mechanism 24 raises and lowers the stage 2 via the support member 23 between the processing position illustrated in FIG. 1 and a transfer position, which is defined below the processing position and where the transfer of the wafer W is performed, as indicated by the two-dot dashed line. A flange portion 25 is attached to the support member 23 below the processing container 1. A bellows 26 is provided between a bottom surface of the processing container 1 and the flange portion 25. The bellows 26 isolates an internal atmosphere of the processing container 1 from an ambient air, and is flexible with the vertical movement of the stage 2.

Three (only two are illustrated) wafer supporting pins 27 are provided near the bottom surface of the processing container 1 so as to protrude upward from a lifting plate 27a. The wafer supporting pins 27 are raised and lowered by a lifting mechanism 28 provided below the processing container 1 via the lifting plate 27a. The wafer supporting pins 27 are inserted through through-holes 2a provided in the stage 2 which is at the transfer position, thus being capable of moving upward and downward with respect to the top surface of the stage 2. The wafer W is transferred between a transfer mechanism (not illustrated) and the stage 2 by raising and lowering the wafer supporting pins 27.

The shower head 3 supplies a processing gas in the form of a shower into the processing container 1. The shower head 3 is made of a metal, is provided to face the stage 2, and has approximately the same diameter as the stage 2. The shower head 3 includes a main body portion 31, a shower plate 32, and the like. The main body portion 31 is secured to the ceiling wall 14 of the processing container 1. The shower plate 32 is connected below the main body portion 31. A gas diffusion space 33 is defined between the main body portion 31 and the shower plate 32. A gas introduction hole 36 is provided in the gas diffusion space 33 so as to pass through the center of the ceiling wall 14 of the process container 1 and the main body portion 31. An annular protrusion 34 is formed on a peripheral edge portion of the shower plate 32 to protrude downward. A gas discharge hole 35 is formed in a flat portion inside the annular protrusion 34. In a state where the stage 2 is present at the processing position, a processing space 38 is formed between the stage 2 and the shower plate 32, and a top surface of the cover member 22 and the annular protrusion 34 are close to each other to form an annular gap 39.

The exhauster 4 evacuates the interior of the process container 1. The exhauster 4 includes an exhaust pipe 41, an exhaust mechanism 42, and the like. The exhaust pipe 41 is connected to the exhaust port 13b. The exhaust mechanism 42 includes a vacuum pump connected to the exhaust pipe 41, a pressure control valve, and the like. During processing, a gas inside the processing container 1 reaches the exhaust duct 13 through the slit 13a, and is exhausted from the exhaust duct 13 through the exhaust pipe 41 by the exhaust mechanism 42.

The gas supplier 5 supplies various processing gases to the shower head 3. The gas supplier 5 includes a gas source 51, a gas line 52, and the like. The gas source 51 includes sources of various processing gases, mass flow controllers, valves (none of which are illustrated), and the like. Various processing gases include gases used in a film forming method according to an embodiment to be described later. Examples of the various processing gases may include an adsorption-inhibiting gas, a silicon-containing gas, a nitriding gas, a modifying gas, a purge gas, and the like. These various processing gases are introduced into the gas diffusion space 33 from the gas source 51 via the gas line 52 and the gas introduction hole 36.

The adsorption-inhibiting gas includes, for example, at least one of a chlorine gas (Cl₂), a nitrogen gas (N₂), and a mixed gas of the chlorine gas and the nitrogen gas (Cl₂/N₂). The silicon-containing gas includes, for example, a dichlorosilane gas (DCS). The nitriding gas includes, for example, an ammonia gas (NH₃) and an argon gas (Ar). The modifying gas includes, for example, a hydrogen gas (H₂) and an argon gas (Ar). The purge gas includes, for example, an argon gas (Ar).

The film forming apparatus is a capacitively coupled plasma apparatus. The stage 2 functions as a lower electrode, and the shower head 3 functions as an upper electrode. The stage 2 is grounded via a condenser (not illustrated). However, for example, the stage 2 may be grounded without a condenser, or may be grounded via a circuit in which a condenser and a coil are combined. The shower head 3 is connected to the RF power supplier 8.

The RF power supplier 8 supplies radio-frequency power (hereinafter also referred to as “RF power”) to the shower head 3. The RF power supplier 8 includes an RF power supply 81, a matcher 82, a feed line 83, and the like. The RF power supply 81 is a power supply that generates the RF power. The RF power has a frequency suitable for plasma generation. The frequency of RF power ranges, for example, from 450 KHz in a low frequency band to 2.45 GHZ in a microwave band. The RF power supply 81 is connected to the main body portion 31 of the shower head 3 via the matcher 82 and the feed line 83. The matcher 82 includes a circuit for matching a load impedance to an internal impedance of the RF power supply 81. In addition, the RF power supplier 8 has been described as supplying the RF power to the shower head 3 serving as the upper electrode, but is not limited thereto. The RF power supplier 8 may be configured to supply the RF power to the stage 2 serving as the lower electrode.

The controller 9 is, for example, a computer, and includes a central processing unit (CPU), a random access memory (RAM), a read only memory (ROM), an auxiliary storage device, etc. The CPU operates based on programs stored in the ROM or the auxiliary storage device, thus controlling the operation of the film forming apparatus. The controller 9 may be provided inside or outside the film forming apparatus. When the controller 9 is provided outside the film forming apparatus, the controller 9 controls the operation of the film forming apparatus through a wired or wireless communication device.

### [Film Forming Method]

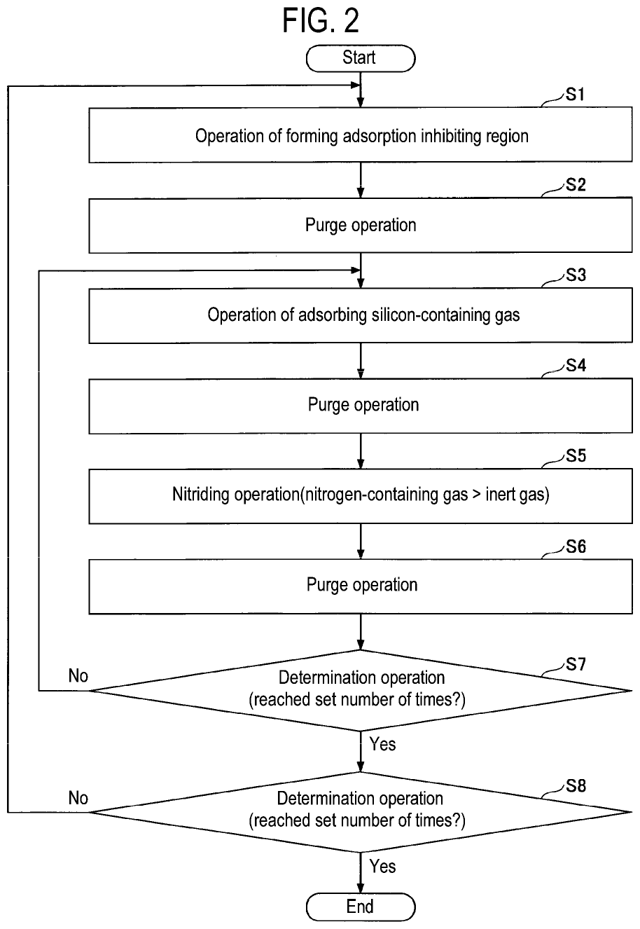

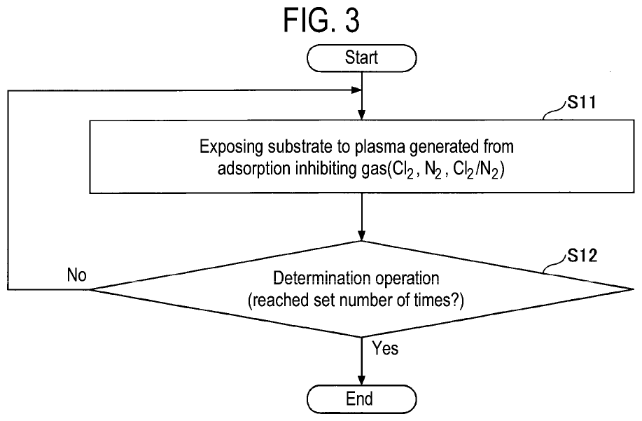

A case where an example of a film forming method according to an embodiment is performed using the film forming apparatus described above will be described with reference to FIGS. 2 and 3. In the present embodiment, a silicon wafer is used as the wafer W, and a trench is formed as a recess in the corresponding silicon wafer. Further, an interior of the trench and a surface of the wafer W are formed of, for example, silicon or an insulating film, and may also partially contain a metal or metal compound.

First, the controller 9 loads the wafer W having the trench formed in the surface thereof into the processing container 1. The controller 9 controls the lifting mechanism 24 to lower the stage 2 to the transfer position. In this state, the controller 9 opens the gate valve 12. Subsequently, the controller 9 loads the wafer W into the processing container 1 via the loading/unloading port 11 by a transfer arm (not illustrated), and places the wafer W on the stage 2, which has been heated to a predetermined temperature (e.g., 600 degrees C. or less) by the heater 21. Subsequently, the controller 9 controls the lifting mechanism 24 to raise the stage 2 up to the processing position, and depressurizes the interior of the processing container 1 to a predetermined degree of vacuum by the exhaust mechanism 42.

### (Operation S1 of Forming Adsorption-inhibiting Region)

Subsequently, Operation S1 of forming an adsorption-inhibiting region is performed. In Operation S1 of forming the adsorption-inhibiting region, the wafer W is exposed to plasma generated from an adsorption-inhibiting gas to form the adsorption-inhibiting region that inhibits the adsorption of a silicon-containing gas onto an upper portion in the trench and onto the surface of the wafer W. Operation S1 of forming the adsorption-inhibiting region includes Operation S11 and Operation S12, as illustrated in FIG. 3, for example.

In Operation S11, the wafer W is exposed to plasma generated from the adsorption-inhibiting gas to form the adsorption-inhibiting region mainly on the upper portion in the trench and on the surface of the wafer W. In the present embodiment, the controller 9 supplies Cl₂, N₂ or Cl₂/N₂ into the processing container 1 from the gas supplier 5 through the shower head 3, and thereafter, supplies RF power to the shower head 3 by the RF power supplier 8. As a result, the plasma is generated from Cl₂, N₂ or Cl₂/N₂ inside the processing container 1 so that active species (reactive species) such as chlorine radicals, chlorine ions, nitrogen radicals, and nitrogen ions are supplied into the trench formed on the surface of the wafer W. The active species are physically or chemically adsorbed onto the surface. Since the adsorbed active species have a function of inhibiting the adsorption of a silicon-containing gas (e.g., DCS) in Operation S3 of adsorbing the silicon-containing gas to be described later, a region where the active species are adsorbed becomes an adsorption-inhibiting region for the silicon-containing gas. Here, the active species easily reach the surface of the wafer W or the upper portion in the trench, but do not significantly reach a deep portion of the trench, that is, a lower portion near the bottom. This is because a high aspect ratio of the trench causes many active species to be adsorbed or deactivated before reaching the deep portion of the trench. Accordingly, the surface of the wafer W and the upper portion in the trench have a high density of adsorbed active species, while the lower portion in the trench contains many un-adsorption sites, resulting in a low density of adsorbed active species.

In Operation S12, the controller 9 determines whether or not the number of executions of Operation S11 has reached a set number of times. The set number of times may be one or more times. In Operation S12, when it is determined that the number of executions of Operation S11 has reached the set number of times, Operation S1 of forming the adsorption-inhibiting region is terminated. On the other hand, when it is determined in Operation S12 that the number of executions of Operation S11 has not reached the set number of times, the processing returns to Operation S11. In addition, between Operation S11 and Operation S12, a purging operation may be performed to remove any gas remaining inside the processing container 1 after Operation S11.

In Operation S1 of forming the adsorption-inhibiting region, the exposing the wafer W to the plasma generated from Cl₂, N₂ or Cl₂/N₂ (Operation S11) is repeated the set number of times to form the adsorption-inhibiting region on the upper portion in the trench and on the surface of the wafer W. At this time, in each repetition of Operation S11, the type of adsorption-inhibiting gas may be the same or different.

For example, when the set number of times is 2 times, Cl₂ may be selected in a first round and Cl₂, N₂ or Cl₂/N₂ may be selected in a second round. In this case, Operation S1 of forming the adsorption-inhibiting region includes exposing the wafer W to plasma generated from Cl₂, and subsequently, exposing the wafer W to plasma generated from Cl₂, N₂ or Cl₂/N₂. Further, for example, N₂ may be selected in the first round and Cl₂, N₂ or Cl₂/N₂ may be selected in the second round. In this case, Operation S1 of forming the adsorption-inhibiting region includes exposing the wafer W to plasma generated from N₂, and subsequently, exposing the wafer W to plasma generated from Cl₂, N₂ or Cl₂/N₂. Further, for example, Cl₂/N₂ may be selected in the first round and Cl₂, N₂ or Cl₂/N₂ may be selected in the second round. In this case, Operation S1 of forming the adsorption-inhibiting region includes exposing the wafer W to plasma generated from Cl₂/N₂, and subsequently, exposing the wafer W to plasma generated from Cl₂, N₂ or Cl₂/N₂. Further, for example, one or more of flow rates, flow rate ratios, plasma exposure times, pressures, and RF powers relating to Cl₂, N₂ or Cl₂/N₂ may be changed in the first round and the second round.

### (Operation S2 of Performing Purging)

Subsequently, Operation S2 is performed for purging. In Operation S2, any gas remaining inside the processing container 1 is removed after Operation S1 of forming the adsorption-inhibiting region. In the present embodiment, the controller 9 supplies an inert gas (e.g., argon gas) from the gas supplier 5 into the processing container 1 through the shower head 3, while simultaneously evacuating the processing container 1 by the exhauster 4. Thus, the gas remaining inside the processing container 1 is discharged together with the inert gas. In addition, Operation S2 may be omitted.

### (Operation S3 of Adsorbing Silicon-Containing Gas)

Subsequently, Operation S3 of adsorbing a silicon-containing gas is performed. In Operation S3 of adsorbing the silicon-containing gas, the silicon-containing gas is supplied to the wafer W so that the silicon-containing gas is adsorbed onto a region excluding the adsorption-inhibiting region to form a silicon (Si)-containing layer. In the present embodiment, the controller 9 supplies DCS as the silicon-containing gas from the gas supplier 5 into the processing container 1 through the shower head 3. DCS is not adsorbed much onto a region where chlorine and nitrogen, which have adsorption-inhibiting functionality, are present, but is adsorbed a lot onto a region where adsorption-inhibiting groups are absent. Accordingly, DCS is adsorbed a lot near the bottom of the trench, and is not adsorbed much onto the surface of the wafer W and the upper portion in the trench. In other words, DCS is adsorbed at a higher density near the bottom of the trench, and is adsorbed at a lower density onto the upper portion in the trench and onto the surface of the wafer W.

### (Operation S4 of Performing Purging)

Subsequently, Operation S4 is performed for purging. In Operation S4, any gas remaining inside the processing container 1 is removed after Operation S3 of adsorbing the silicon-containing gas. In the present embodiment, the controller 9 supplies an inert gas (e.g., argon gas) from the gas supplier 5 into the processing container 1 through the shower head 3, while simultaneously evacuating the processing container 1 by the exhauster 4. Thus, the gas remaining inside the processing container 1 is discharged together with the inert gas. In addition, Operation S4 may be omitted.

### (Operation S5 of Performing Nitridation)

Subsequently, Operation S5 is performed for nitridation. In Operation S5, the wafer W is exposed to plasma generated from a nitriding gas, which includes a nitrogen-containing gas and an inert gas, thereby nitriding the silicon-containing layer formed on the surface of the wafer W and in the trench to form a silicon nitride film. In Operation S5, flow rates of the nitrogen-containing gas and the inert gas are adjusted such that the flow rate of the nitrogen-containing gas is greater than the flow rate of the inert gas. In the present embodiment, the controller 9 supplies an ammonia gas and an argon gas as the nitrogen-containing gas and the inert gas, respectively, from the gas supplier 5 into the processing container 1 through the shower head 3, and thereafter, supplies RF power to the shower head 3 by the RF power supplier 8. At this time, the controller 9 adjusts the flow rate of the ammonia gas to be greater than the flow rate of the argon gas. In other words, the controller 9 adjusts the flow rates such that a flow rate ratio of the ammonia gas to the argon gas (hereinafter referred to as “NH₃/Ar ratio”) is greater than 1. Within the processing container 1, plasma is generated from the ammonia gas and the argon gas, and active species for nitriding are supplied to the surface of the wafer W and into the trench. The active species react with the silicon-containing layer formed in the trench so that a molecular layer of the silicon nitride film is formed as a reaction product. Here, since the silicon-containing layer is predominantly formed near the bottom in the trench, a significant amount of silicon nitride film is formed near the bottom in the trench.

### (Operation S6 of Performing Purging)

Subsequently, Operation S6 is performed for purging. In Operation S6, any gas remaining inside the processing container 5 is removed after Operation S5. In the present embodiment, the controller 9 supplies an inert gas (e.g., argon gas) from the gas supplier 5 into the processing container 1 through the shower head 3, while simultaneously evacuating the processing container 1 by the exhauster 4. Thus, the gas remaining inside the processing container 1 is discharged together with the inert gas. In addition, Operation S6 may be omitted.

### (Operation S7 of Performing Determination)

Subsequently, Operation S7 is performed for determination. In Operation S7, the controller 9 determines whether or not the number of repetitions from Operation S3 of adsorbing the silicon-containing gas to Operation S6 of performing the purging has reached a set number of repetitions. The set number of repetitions is determined based on, for example, a desired film thickness of the silicon nitride film to be formed. In Operation S7, when it is determined that the number of repetitions has reached the set number of repetitions, the processing proceeds to Operation S8 of performing determination. On the other hand, when it is determined in Operation S7 that the number of repetitions has not reached the set number of repetitions, the processing returns to Operation S3 of adsorbing the silicon-containing gas.

### (Operation S8 of Performing Determination)

Subsequently, Operation S8 is performed for determination. In Operation S8, the controller 9 determines whether or not the number of repetitions from Operation S1 of forming the adsorption-inhibiting region to Operation S7 of performing the determination has reached a set number of repetitions. The set number of repetitions is determined based on, for example, a desired shape of the silicon nitride film to be formed. In Operation S8, when it is determined that the number of repetitions has reached the set number of repetitions, the processing is terminated. On the other hand, when it is determined in Operation S8 that the number of repetitions has not reached the set number of repetitions, the processing returns to Operation S1 of forming the adsorption-inhibiting region.

As described above, according to the film forming method of the embodiment, a cycle including Operation S1 of forming the adsorption-inhibiting region to Operation S6 of performing the purging is repeated to deposit the silicon nitride starting from the bottom surface of the trench without blocking the opening of the trench. Then, the silicon nitride film having a high bottom-up property, in which a V-shaped cross section is formed without blocking the opening, may be formed. As a result, it is possible to embed a high-quality silicon nitride film in the trench without generating voids.

Further, according to the film forming method of the embodiment, in Operation S5, flow rates of the nitrogen-containing gas and the inert gas are adjusted such that the flow rate of the nitrogen-containing gas is greater than the flow rate of the inert gas. This makes it possible to form the silicon nitride film having a high bottom-up property. The reason for this will be described later.

In addition, the film forming method of the embodiment may further include a modifying operation. The modifying operation is performed, for example, after at least one of Operation S1 of forming the adsorption-inhibiting region, Operation S3 of adsorbing the silicon-containing gas, or Operation S5 of performing nitridation. In the modifying operation, the wafer W is exposed to plasma generated from a modifying gas to modify the silicon-containing layer and the silicon nitride film. In the present embodiment, the controller 9 supplies a hydrogen gas and an argon gas as the modifying gas from the gas supplier 5 into the processing container 1 through the shower head 3, and thereafter, supplies RF power to the shower head 3 by the RF power supplier 8. Thus, the plasma is generated from the hydrogen gas and the argon gas inside the processing container 1, and active species are supplied to the surface of the wafer W and into the trench. As a result, the silicon-containing layer is modified. The modification of the silicon-containing layer includes, for example, removing halogens contained in the silicon-containing layer. Further, a second cycle and subsequent cycles also include removing halogens or excess NHₓ groups contained in the silicon nitride film. By removing the halogens or excess NHₓ groups, for example, a wet etching rate is improved. In the modifying operation, a flow rate ratio of the hydrogen gas to the argon gas (H₂/Ar ratio) is adjusted to, for example, a range from 0.1 to 2.0.

### EXAMPLES

A description will be given of Examples where an embedding property was evaluated when a silicon nitride film was formed in a trench formed in the surface of the wafer W by the film forming method of the embodiment as described above.

In Example 1, the silicon nitride film was formed in the trench by the film forming method illustrated in FIG. 2. In Example 1, the NH₃/Ar ratio in Operation S5 of performing nitridation was set to 3. Further, in Example 1, the modifying operation was performed after Operation S6 of performing purging, and the H₂/Ar ratio in the modifying operation was set to 0.3. Subsequently, six positions were defined as Z1 to Z6 from a shallower depth in the trench, and a film thickness of the deposited silicon nitride film was measured at each of these positions. Further, a film formation amount per cycle (hereinafter referred to as “growth per cycle (GPC)”) of the silicon nitride film was calculated by dividing the measured film thickness of the silicon nitride film by the set number of repetitions in Operation S7 of performing determination. Further, an etching rate (hereinafter referred to as “wet etching rate (WER)”) when the silicon nitride film formed in the trench was etched with 0.5% of dilute hydrofluoric acid (DHF) for 60 seconds was measured.

In Example 2, the NH₃/Ar ratio in Operation S5 of performing nitridation remained unchanged, and the H₂/Ar ratio in the modifying operation was changed to 0.5, as compared with Example 1.

In Example 3, the NH₃/Ar ratio in Operation S5 of performing nitridation was changed to 7, and the H₂/Ar ratio in the modifying operation was changed to 1.0, as compared with Example 1.

In Comparative Example 1, the NH₃/Ar ratio in Operation S5 of performing nitridation was changed to 1, and the H₂/Ar ratio in the modifying operation remained unchanged, as compared with Example 1.

That is, the NH₃/Ar ratio in Operation S5 of performing nitridation and the H₂/Ar ratio in the modifying operation in Examples 1 to 3 and Comparative Example 1 are as shown in Table 1 below.

TABLE 1

| | NH₃/Ar ratio | H₂/Ar ratio |
|---|---|---|
| Comparative Example 1 | 1 | 0.3 |
| Example 1 | 3 | 0.3 |
| Example 2 | 3 | 0.5 |
| Example 3 | 7 | 1.0 |

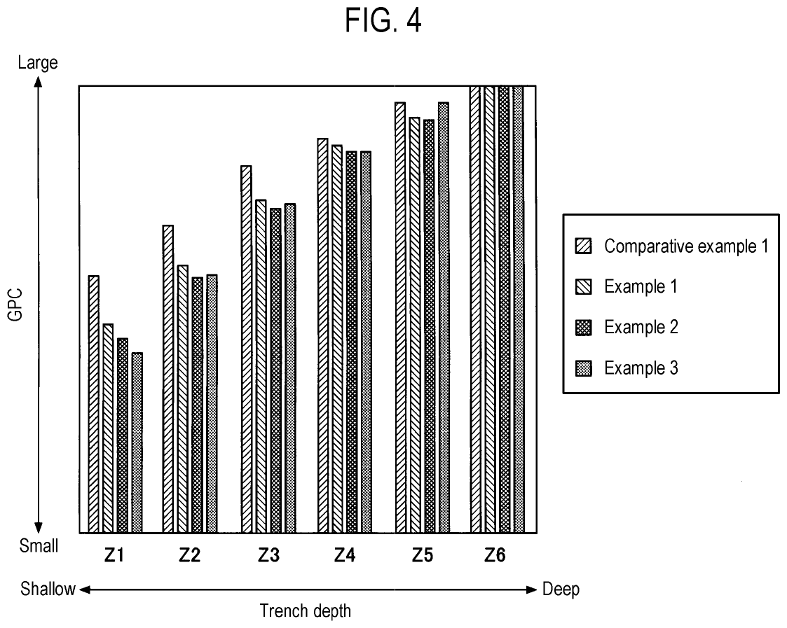

FIG. 4 is a diagram illustrating results obtained by evaluating an embedding property of a silicon nitride film with respect to a trench. In FIG. 4, among positions Z1 to Z6, the position Z1 corresponds to the shallowest position, that is, the upper portion in the trench, while the position Z6 corresponds to the deepest position, that is, the lower portion in the trench. Further, FIG. 4 illustrates a normalized GPC at the position Z6 for all Examples 1 to 3 and Comparative Example 1.

As illustrated in FIG. 4, it can be appreciated that in Examples 1 to 3, the GPC is smaller at the upper portion in the trench (at a position where the depth of the trench is shallower), as compared with Comparative Example 1. From this result, it was found that the NH₃/Ar ratio greater than 1 in Operation S5 of performing nitridation leads to a larger opening angle of the V-shaped cross section of the silicon nitride film embedded in the trench. In other words, it was found that it is possible to form a silicon nitride film having a high bottom-up property. This is presumed to be due to the NH₃/Ar ratio greater than 1 in Operation S5 of performing nitridation, which leads to a change in plasma conditions (especially excited species of Ar), resulting in the formation of a surface more prone to the adsorption of the adsorption-inhibiting gas at the upper portion than the lower portion in the trench.

Further, when comparing Example 1 with Example 2, it can be appreciated that the GPC at the position Z1 is smaller in Example 2 than in Example 1. From this result, it was found that changing the H₂/Ar ratio in the modifying operation from 0.3 to 0.5 leads to a larger opening angle of the V-shaped cross section of the silicon nitride film embedded in the trench. In other words, it was found that it is possible to form a silicon nitride film having a high bottom-up property.

Further, when comparing Example 2 with Example 3, it can be appreciated that the GPC at the position Z1 is smaller in Example 3 than in Example 2, while the GPC at the positions Z2 to Z6 is larger in Example 3 than in Example 2. From this result, it was found that setting the NH₃/Ar ratio to 7 in Operation S5 of performing nitridation and the H₂/Ar ratio in the modifying operation to 1.0 leads to a larger opening angle of the V-shaped cross-section of the silicon nitride film embedded in the trench. In other words, it was found that it is possible to form the silicon nitride film having a high bottom-up property.

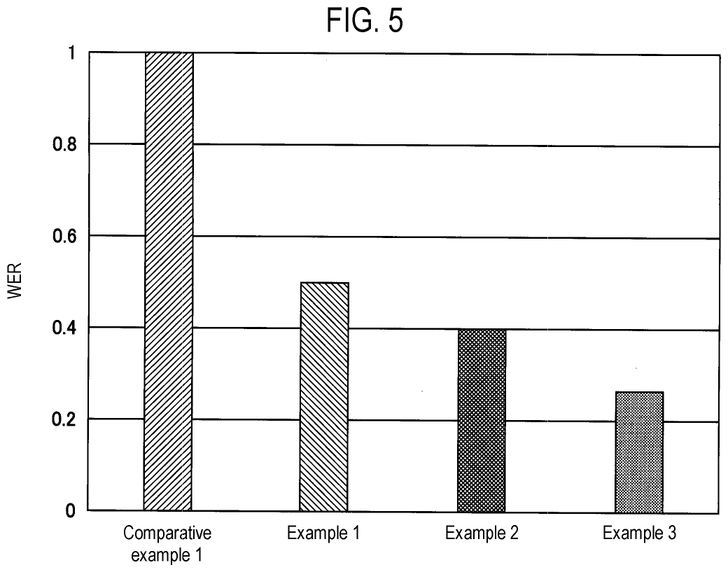

FIG. 5 is a diagram illustrating evaluation results of WER of the silicon nitride film embedded in the trench. FIG. 5 illustrates WERs of Examples 1 to 3 when the WER of Comparative Example 1 is normalized.

As illustrated in FIG. 5, it can be appreciated that the WERs of Examples 1 to 3 are equal to or less than half of the WER of Comparative Example 1. From these results, it was found that Examples 1 to 3 exhibit improved wet etching resistance compared to Comparative Example 1. In particular, the WER of Example 3 is approximately ¼ of the WER of Comparative Example 1, which demonstrates a significant improvement in wet etching resistance.

As described above, in Examples 1 to 3, since the silicon nitride film having a high bottom-up property can be formed, it is possible to suppress generation of voids in a more effective manner. Further, since aspect ratios in patterns can be maintained at a relatively low level, radicals may be easily supplied to seams. Therefore, it is considered that it is possible to embed a high-quality silicon nitride film in the trench, which improves the wet etching resistance, for example. In particular, when forming a silicon nitride film at low temperatures (e.g., below 400 degrees C.), it is known that insufficient nitridation tends to occur, which makes it easy for the wet etching to proceed from the seams. In Examples 1 to 3, it is considered that since the aspect ratios in the patterns can be maintained at a relatively low level, a high wet etching resistance is exhibited even at low temperatures. Further, it is considered that even in cases where the trench exhibits a significant bowing shape, the generation of voids can be more effectively suppressed.

The embodiments disclosed herein should be considered to be exemplary and not limitative in all respects. The above embodiments may be omitted, replaced or modified in various embodiments without departing from the scope of the appended claims and their gist.

In the above embodiment, the case where the adsorption-inhibiting gas is the chlorine gas (Cl₂), the nitrogen gas (N₂), or the mixed gas of the chlorine gas and the nitrogen gas (Cl₂/N₂) has been described, but the present disclosure is not limited thereto. For example, gases including at least one of a halogen gas and a non-halogen gas may be used as the adsorption-inhibiting gas. A fluorine gas (F₂), a chlorine gas (Cl₂), a hydrogen fluoride gas (HF), or the like may be used as the halogen gas. A nitrogen gas (N₂), a silane coupling agent, or the like may be used as the non-halogen gas.

In the above embodiment, the case where the silicon-containing gas is the dichlorosilane gas (DCS) has been described, but the present disclosure is not limited thereto. For example, gases containing halogens such as chlorine (Cl), bromine (Br), iodine (I), and the like and silicon (Si) may be used as the silicon-containing gas.

In the above embodiment, the case where the nitrogen-containing gas and the inert gas are the ammonia gas (NH₃) and the argon gas (Ar) has been described, but the present disclosure is not limited thereto. For example, an ammonia gas (NH₃), a hydrazin gas (N₂H₂), a nitrogen gas (N₂), or the like may be used as the nitrogen-containing gas, and these may also be combined. Further, for example, the nitrogen-containing gas may contain a hydrogen gas (H₂). Further, for example, an argon gas (Ar), helium gas (He), and the like may be used as the inert gas, and these may also be combined.

In the above embodiment, the case where the purge gas used in Operations S2, S4, and S6 of performing purging is the argon gas (Ar) has been described, but the present disclosure is not limited thereto. For example, an argon gas (Ar), a nitrogen gas (N₂), or the like may be used as the purge gas, and these may also be combined. Further, evacuation may be performed under a vacuum condition without using the purge gas.

In the above embodiment, the case where the film forming apparatus is the capacitively coupled plasma apparatus has been described, but the present disclosure is not limited thereto. For example, the film forming apparatus may be a plasma apparatus that uses any other plasma sources such as inductively coupled plasma, surface wave plasma (microwave plasma), magnetron plasma, remote plasma, and the like.

In the above embodiment, the case where the film forming apparatus is the single wafer type apparatus that processes wafers one by one has been described, but the present disclosure is not limited thereto. For example, the film forming apparatus may be a batch type apparatus that processes a plurality of wafers at once. Further, for example, the film forming apparatus may be a semi-batch type apparatus that revolves a plurality of wafers placed on a rotation table inside a processing container, by the rotation table, thereby sequentially passing the wafers through a region to which a first gas is supplied and a region to which a second gas is supplied so as to process the wafers. Further, for example, the film forming apparatus may be a multi-sheet film forming apparatus including a plurality of stages inside one process container.

This international application claims priority based on Japanese Patent Application No. 2021-071940 filed on Apr. 21, 2021, and the entire disclosure of the application is incorporated herein in its entirety by reference.

### EXPLANATION OF REFERENCE NUMERALS

1: processing container, 5: gas supplier, 9: controller

1-12. (canceled)

13. A film forming method of forming a film in a recess formed in a surface of a substrate, the film forming method comprising:
forming an adsorption-inhibiting region by supplying an adsorption-inhibiting gas to the substrate;
adsorbing a silicon-containing gas onto a region excluding the adsorption-inhibiting region; and
forming a silicon nitride film by exposing the substrate, onto which the silicon-containing gas has been adsorbed, to plasma generated from a nitriding gas,
wherein the nitriding gas includes a nitrogen-containing gas and an inert gas, and
wherein the nitrogen-containing gas has a flow rate greater than a flow rate of the inert gas.

14. The film forming method of claim 13, wherein a cycle including the forming the adsorption-inhibiting region, the adsorbing the silicon-containing gas, and the forming the silicon nitride film is repeated.

15. The film forming method of claim 13, wherein the nitrogen-containing gas includes at least one of an ammonia gas, a hydrazin gas, or a nitrogen gas, and
wherein the inert gas is an argon gas.

16. The film forming method of claim 13, wherein the forming the adsorption-inhibiting region includes at least one of exposing the substrate to plasma generated from a halogen gas or exposing the substrate to plasma generated from a non-halogen gas.

17. The film forming method of claim 13, wherein the forming the adsorption-inhibiting region includes exposing the substrate to plasma generated from a halogen gas and subsequently, exposing the substrate to plasma generated from a non-halogen gas.

18. The film forming method of claim 13, wherein the forming the adsorption-inhibiting region includes exposing the substrate to plasma generated from a non-halogen gas and subsequently, exposing the substrate to plasma generated from a halogen gas.

19. The film forming method of claim 13, wherein the forming the adsorption-inhibiting region repeats a cycle including exposing the substrate to plasma generated from a halogen gas and exposing the substrate to plasma generated from a non-halogen gas.

20. The film forming method of claim 13, wherein the forming the adsorption-inhibiting region includes exposing the substrate to plasma generated from a mixed gas of a halogen gas and a non-halogen gas and subsequently, exposing the substrate to plasma generated from either the halogen gas or the non-halogen gas.

21. The film forming method of claim 16, wherein the halogen gas is a chlorine gas, and the non-halogen gas is a nitrogen gas.

22. The film forming method of claim 13, further comprising: modifying the substrate by exposing the substrate to plasma generated from a modifying gas, which is performed after at least one of the forming the adsorption-inhibiting region, the adsorbing the silicon-containing gas, or the forming the silicon nitride film.

23. The film forming method of claim 22, wherein the modifying gas includes a hydrogen gas and an inert gas, and
wherein a flow rate ratio of the hydrogen gas to the inert gas is in a range from 0.1 to 2.0.

24. The film forming method of claim 20, wherein the halogen gas is a chlorine gas, and the non-halogen gas is a nitrogen gas.

25. A film forming apparatus comprising:
a processing container in which a substrate having a recess formed in a surface thereof is accommodated;
a gas supplier configured to supply an adsorption-inhibiting gas, a silicon-containing gas, and a nitrogen-containing gas into the processing container; and
a controller,
wherein the controller is configured to control the gas supplier so as to perform:
forming an adsorption-inhibiting region by supplying the adsorption-inhibiting gas to the substrate;
adsorbing the silicon-containing gas to a region excluding the adsorption-inhibiting region; and
forming a silicon nitride film by exposing the substrate, onto which the silicon-containing gas has been adsorbed, to plasma generated from a nitriding gas,
wherein the nitriding gas includes the nitrogen-containing gas and an inert gas, and
wherein the nitrogen-containing gas has a flow rate greater than a flow rate of the inert gas.
